(19) United States
(12) Patent Application Publication
(10) Pub. No.: US 2025/0359008 A1
(43) Pub. Date: Nov. 20, 2025

(54) INTEGRATION OF MEMORY CELL AND LOGIC CELL

(71) Applicant: Taiwan Semiconductor Manufacturing Company, Ltd., Hsin-Chu (TW)

(72) Inventors: Ping-Wei Wang, Hsin-Chu (TW); Lien-Jung Hung, Taipei (TW); Jui-Lin Chen, Taipei City (TW)

(21) Appl. No.: 19/285,875

(22) Filed: Jul. 30, 2025

Related U.S. Application Data
(63) Continuation of application No. 18/349,298, filed on Jul. 10, 2023.
(60) Provisional application No. 63/489,214, filed on Mar. 9, 2023.

(51) Int. Cl. H10B 10/00

(52) U.S. Cl. CPC H10B 10/18; H10B 10/125

(57) ABSTRACT

A semiconductor structure includes a memory cell, a logic cell, and a transition region between the memory cell and the logic cell. The memory cell includes a first active region and a plurality of first gate structures with a gate pitch. The logic cell includes a second active region and a plurality of second gate structures with the gate pitch. The transition region includes a first dielectric feature and a second dielectric feature. The first dielectric feature divides the first active region into a first segment partially in the transition region and a second segment fully in the transition region. The second dielectric feature divides the second active region into a third segment partially in the transition region and a fourth segment fully in the transition region.

### PRIORITY DATA

This is a continuation application of U.S. patent application Ser. No. 18/349,298, filed Jul. 10, 2023, which claims benefit of U.S. Provisional Patent Application No. 63/489,214, filed Mar. 9, 2023, each of which is incorporated herein by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Memories are commonly used in ICs. For example, a static random-access memory (SRAM) is a volatile memory used in electronic applications where high speed, low power consumption, and simplicity of operation are needed. Embedded SRAM is particularly popular in high-speed communications, image processing, and system-on-chip (SOC) applications. SRAM has the advantage of being able to hold data without requiring a refresh. An SRAM structure includes memory cells and logic cells. During IC design, designers retrieve the required cells from the cell libraries and position them in desired locations. Subsequently, routing is performed to establish connections between the cells and other circuit blocks, creating the desired integrated circuit. The placement of memory cells and logic cells follows predefined design rules. For instance, cells are positioned in close proximity to one another, with the space between them determined by predefined rules. However, this reserved space between cells and cell boundaries results in a significant increase in the overall device size. Moreover, it contains structures that increase the fabrication complexity and introduce the risk of defects, impacting circuit performance. The resulting circuit's performance is thus degraded. The layout patterns and configurations have an impact on the yield and design performance of the IC. Hence, there is a need for an IC structure to address the aforementioned issues.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a block diagram of a semiconductor device that includes a memory macro, in accordance with some embodiments of the present disclosure.

FIG. 2 illustrates a circuit schematic for a static random-access memory (SRAM) cell, in accordance with some embodiments of the present disclosure.

FIG. 3 illustrates a perspective view of a multi-gate transistor, in accordance with some embodiments of the present disclosure.

FIG. 4 illustrates a layout of the SRAM cell as in FIG. 2, in accordance with some embodiments of the present disclosure.

FIGS. 5 and 6 illustrate block diagrams of a portion of the memory macro as in FIG. 1, in accordance with some embodiments of the present disclosure.

FIGS. 7, 9, 10, 11, 12, and 14 illustrate layouts of a portion of the memory macro as in FIG. 1, in accordance with some embodiments of the present disclosure.

FIGS. 8, 13, and 15 illustrate cross-sectional views along a cut line of the layouts as in FIGS. 7, 12, and 14, respectively, in accordance with some embodiments of the present disclosure.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within +/−10% of the number described, unless otherwise specified. For example, the term “about 5 nm” encompasses the dimension range from 4.5 nm to 5.5 nm.

The present disclosure is generally related to static random-access memories (SRAM) structures including memory cells and logic cells. The memory cells are also referred to as bit cells, and are configured to store memory bits. The memory cells may be arranged in rows and columns of an array. The logic cells may be standard cells (STD cells), such as inventor (INV), AND, OR, NAND, NOR, Flip-flip, SCAN and so on. The logic cells are disposed around the memory cells, and are configured to implement various logic functions. The placement of memory cells and logic cells follows predefined design rules. For instance, dummy cells may be placed in a reserved space between the memory cells and the logic cells to facilitate uniformity in fabrication and/or performance of the memory cells. However, this reserved space between cells results in a significant increase in the overall device size. Various SRAM structures with a reduced transition region between the memory cells and logic cells and corresponding layouts are provided in accordance with some exemplary embodiments. Some variations of some embodiments are discussed. Throughout the various views and illustrated embodiments, like reference numbers are used to designate like elements.

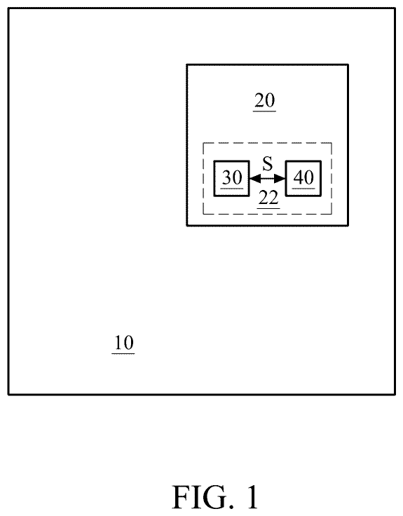

Reference now is made to FIG. 1. FIG. 1 is a simplified block diagram of a semiconductor device (or IC) 10, in accordance with some embodiments of the present disclosure. The semiconductor device 10 can be, e.g., a microprocessor, an application specific integrated circuit (ASIC), a field programmable gate array (FPGA), a digital signal processor (DSP), or a portion thereof, that includes various passive and active microelectronic devices such as resistors, capacitors, inductors, diodes, p-type field effect transistors (PFETs), n-type field effect transistors (NFETs), FinFET, gate-all-around (GAA) transistors (such as nanosheet FETs or nanowire FETs), other types of multi-gate FETs, metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, memory devices, other suitable components, or combinations thereof. The exact functionality of the semiconductor device 10 is not a limitation to the provided subject matter.

The semiconductor device 10 includes a circuit macro (hereinafter, macro) 20. In some embodiments, the macro 20 is a static random-access memory (SRAM) macro, such as a single-port SRAM macro, a dual-port SRAM macro, or other types of SRAM macro. However, the present disclosure contemplates embodiments, where macro 20 is another type of memory, such as a dynamic random-access memory (DRAM), a non-volatile random access memory (NVRAM), a flash memory, or other suitable memory. FIG. 1 has been simplified for the sake of clarity to better understand the inventive concepts of the present disclosure. Additional features can be added in the memory macro 20, and some of the features described below can be replaced, modified, or eliminated in other embodiments of the memory macro 20.

In some embodiments, the macro 20 includes memory cells and peripheral circuits. The memory cells are also referred to as bit cells, and are configured to store memory bits. The peripheral cells are also referred to as logic cells that are disposed around the bit cells, and are configured to implement various logic functions. The logic functions of the logic cells include, for example, write and/or read decoding, word line selecting, bit line selecting, data driving and memory self-testing. The logic functions of the logic cells described above are given for the explanation purpose. Various logic functions of the logic cells are within the contemplated scope of the present disclosure. In the illustrated embodiment, the macro 20 includes a circuit region 22 in which at least a memory cell block 30 and at least a logic cell block 40 are positioned in close proximity to each other. The memory cell block 30 includes at least one memory cell. Generally, the memory cell block 30 may include many memory cells arranged in rows and columns of an array. The logic cell block 40 includes at least one logic cell. Generally, the logic cell block 40 may include many logic cells to provide read operations and/or write operations to the memory cells in the memory cell block 40. Transistors in the one or more memory cell blocks 40 and the one or more logic cell blocks 40 may be implemented with various PFETs and NFETs such as planar transistors or non-planar transistors including various FinFET transistors, GAA transistors, or a combination thereof. GAA transistors refer to transistors having gate electrodes surrounding transistor channels, such as vertically-stacked gate-all-around horizontal nanowire or nanosheet MOSFET devices. The following disclosure will continue with one or more GAA examples to illustrate various embodiments of the present disclosure. It is understood, however, that the application should not be limited to a particular type of device, except as specifically claimed. For example, aspects of the present disclosure may also apply to implementation based on FinFETs or planar FETs.

The memory cell block 30 is separated from the logic cell block 40 by a distance S, sparing a reserved space between the memory cell block 30 and the logic cell block 40. Edge dummy cells and/or well strap cells of various sizes may be introduced in the reserved space to serve as a transition from the memory cell block 30 to the logic cell block 40. For example, the memory cell block 30 and the logic cell block 40 may each have respective edge dummy cells. Edge dummy cells specialized for the memory cell block 30 promote uniformity in fabrication and/or performance of memory cells in the memory cell block 30. Edge dummy cells specialized for the logic cell block 40 promote uniformity in fabrication and/or performance of logic cells in the logic cell block 40. Well strap cells specialized for the memory cell block 30 promote stability of potentials of n-wells and p-wells in the memory cell block 30. Well strap cells specialized for the logic cell block 40 promote stability of potentials of n-wells and p-wells in the logic cell block 40. The distance S would have to be sufficiently large to accommodate these non-functional cells, resulting in a significant increase in the overall device size.

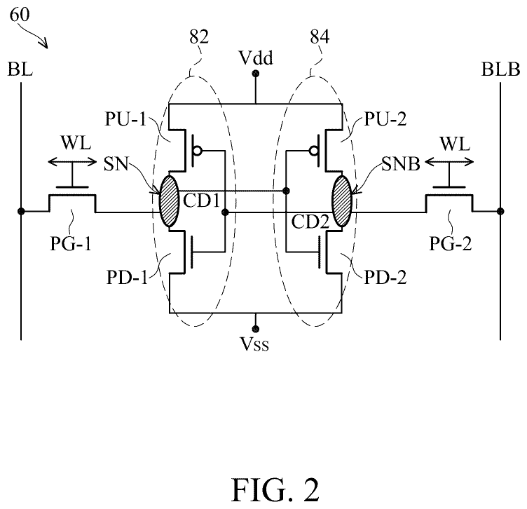

FIG. 2 is a circuit diagram of an exemplary SRAM cell 60, which can be implemented as a memory cell of a SRAM array, according to various aspects of the present disclosure. In some implementations, SRAM cell 60 is implemented in one or more memory cell blocks 30 of the macro 20 (FIG. 1). In the illustrated embodiment, the SRAM cell 60 is a single-port (SP) six-transistor (6T) SRAM cell. In various embodiments, the SRAM cell 60 may be other types of memory cells, such as dual-port memory cell or a memory cell having more than six transistors. FIG. 2 has been simplified for the sake of clarity to better understand the inventive concepts of the present disclosure. Additional features can be added in single-port SRAM cell 60, and some of the features described below can be replaced, modified, or eliminated in other embodiments of single-port SRAM cell 60.

The exemplary SRAM cell 60 includes six transistors: a pass-gate transistor PG-1, a pass-gate transistor PG-2, a pull-up transistor PU-1, a pull-up transistor PU-2, a pull-down transistor PD-1, and a pull-down transistor PD-2. In operation, the pass-gate transistor PG-1 and the pass-gate transistor PG-2 provide access to a storage portion of the SRAM cell 60, which includes a cross-coupled pair of inverters, an inverter 82 and an inverter 84. The inverter 82 includes the pull-up transistor PU-1 and the pull-down transistor PD-1, and the inverter 84 includes the pull-up transistor PU-2 and the pull-down transistor PD-2. In some implementations, the pull-up transistors PU-1, PU-2 are configured as p-type FinFET transistors or p-type GAA transistors, and the pull-down transistors PD-1, PD-2 are configured as n-type FinFET transistors or n-type GAA transistors.

A gate of the pull-up transistor PU-1 interposes a source (electrically coupled with a power supply voltage (V_{DD})) and a first common drain (CD1), and a gate of pull-down transistor PD-1 interposes a source (electrically coupled with a power supply voltage (V_{SS}), which may be an electric ground) and the first common drain. A gate of pull-up transistor PU-2 interposes a source (electrically coupled with the power supply voltage (V_{DD})) and a second common drain (CD2), and a gate of pull-down transistor PD-2 interposes a source (electrically coupled with the power supply voltage (V_{SS})) and the second common drain. In some implementations, the first common drain (CD1) is a storage node (SN) that stores data in true form, and the second common drain (CD2) is a storage node (SNB) that stores data in complementary form. The gate of the pull-up transistor PU-1 and the gate of the pull-down transistor PD-1 are coupled with the second common drain (CD2), and the gate of the pull-up transistor PU-2 and the gate of the pull-down transistor PD-2 are coupled with the first common drain (CD1). A gate of the pass-gate transistor PG-1 interposes a source (electrically coupled with a bit line BL) and a drain, which is electrically coupled with the first common drain (CD1). A gate of the pass-gate transistor PG-2 interposes a source (electrically coupled with a complementary bit line BLB) and a drain, which is electrically coupled with the second common drain (CD2). The gates of the pass-gate transistors PG-1, PG-2 are electrically coupled with a word line WL. In some implementations, the pass-gate transistors PG-1, PG-2 provide access to the storage nodes SN, SNB during read operations and/or write operations. For example, the pass-gate transistors PG-1, PG-2 couple the storage nodes SN, SNB respectively to the bit lines BL, BLB in response to a voltage applied to the gates of the pass-gate transistors PG-1, PG-2 by the word line WL.

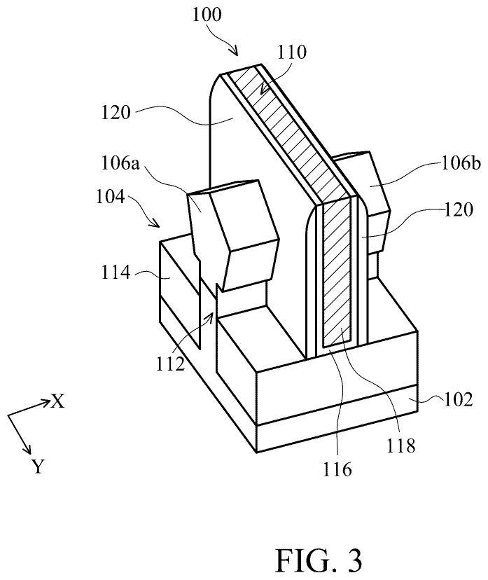

FIG. 3 illustrates a perspective view of a multi-gate transistor 100, which may serve as any of the transistors in the SRAM cell 60 (FIG. 2), including the pull-up transistor PU-1, the pull-up transistor PU-2, the pull-down transistor PD-1, the pull-down transistor PD-2, the pass-gate transistor PG-1, and the pass-gate transistor PG-2. In some embodiments, the multi-gate transistor 100 is a FinFET transistor that includes a channel region comprised of a fin-like structure. In some embodiments, the multi-gate transistor 100 is a GAA transistor that includes a channel region comprised of vertically-stacked horizontally-oriented nanostructures (e.g., nanowires or nanosheets).

In the illustrated embodiment, the multi-gate transistor 100 is formed on a substrate 102. The substrate 102 may comprise an elementary (single element) semiconductor, such as silicon, germanium, and/or other suitable materials; a compound semiconductor, such as silicon carbide, gallium arsenic, gallium phosphide, indium phosphide, indium arsenide, indium antimonide, and/or other suitable materials; an alloy semiconductor such as SiGe, GaAsP, AlInAs, AlGaAs, GaInAs, GaInP, GaInAsP, and/or other suitable materials. The substrate 102 may be a single-layer material having a uniform composition. Alternatively, the substrate 102 may include multiple material layers having similar or different compositions suitable for IC device manufacturing. In one example, the substrate 102 may be a silicon-on-insulator (SOI) substrate having a semiconductor silicon layer formed on a silicon oxide layer. In another example, the substrate 102 may include a conductive layer, a semiconductor layer, a dielectric layer, other layers, or combinations thereof. Various doped regions, such as source/drain (S/D) regions, may be formed in or on the substrate 102. The doped regions may be doped with n-type dopants, such as phosphorus or arsenic, and/or p-type dopants, such as boron, depending on design requirements. The doped regions may be formed directly on the substrate 102, in a P-well structure, in an N-well structure, in a dual-well structure, or using a raised structure. Doped regions may be formed by implantation of dopant atoms, in-situ doped epitaxial growth, and/or other suitable techniques.

A three-dimensional active region 104 is formed on the substrate 102. An active region for a transistor refers to the area where a source region, a drain region, and a channel region under a gate structure of the transistor are formed.

Because the active regions are sometimes disposed in and defined by a silicon-oxide containing isolation feature (such as a shallow trench isolation, or STI), the active regions may be referred to as oxide-definition regions or “ODs”. The active region 104 includes a source region 106a, a drain region 106b, a channel region (under the gate structure 110) sandwiched by the source region 106a and the drain region 106b, and a fin base 112 on which the source region 106a, the drain region 106b, and the channel region are disposed on. The source region 106a and the drain region 106b are also collectively referred to as the source/drain (S/D) regions 106. In some embodiments, the source/drain regions 106 are formed of epitaxially-grown features and are also referred to as source/drain features 106 or source/drain epitaxial features 106. The fin base 112 protrudes from the substrate 102. In a FinFET transistor, the channel region under the gate structure 110 may be a fin-like structure continuously extending upwardly from the fin base 112. In a GAA transistor, the channel region under the gate structure 110 may be vertically-stacked horizontally-oriented nanostructures suspended above the fin base 112. The suspended nanostructures connect the opposing source region 106a and drain region 106b.

An SRAM cell includes multiple active regions. In some embodiments, the formation of the active regions, such as the three-dimensional active regions 104 illustrated in FIG. 3, includes patterning a top portion of the substrate in a patterning process. For example, the active regions 104 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the active region 104.

In some embodiments, an isolation structure 114 is deposited on sidewalls of the fin base 112. The isolation structure 114 may electrically isolate the active region 104 from other active regions. In some embodiments, the isolation structure 114 is shallow trench isolation (STI), field oxide (FOX), or another suitable electrically insulating features.

Still referring to FIG. 3, in some embodiments, the gate structure 110 includes a gate dielectric 116 and a gate electrode 118 formed over the gate dielectric 116. In a FinFET transistor, the gate structure 110 is positioned over sidewalls and a top surface of a fin. In a GAA transistor, the gate structure 110 wraps around each of the channel layers (e.g., nanowire or nanosheet). Therefore, the gate structure 110 defines a portion of the active region 104 thereunder as a channel region. In some embodiments, the gate dielectric 116 is a high dielectric constant (high-k) dielectric material. A high-k dielectric material has a dielectric constant (k) higher than that of silicon dioxide. Examples of high-k dielectric materials include hafnium oxide, zirconium oxide, aluminum oxide, silicon oxynitride, hafnium dioxide-alumina alloy, hafnium silicon oxide, hafnium silicon oxynitride, hafnium tantalum oxide, hafnium titanium oxide, hafnium zirconium oxide, another suitable high-k material, or a combination thereof. In some embodiments, the gate electrode 118 is made of a conductive material, such as aluminum (Al), copper (Cu), tungsten (W), titanium (Ti), tantalum (Ta), or another applicable material.

In some embodiments, gate spacers 120 are deposited on sidewalls of the gate structure 110. In some embodiments, the gate spacers 120 are made of silicon nitride, silicon oxynitride, silicon carbide, another suitable material, or a combination thereof.

In some embodiments, portions of the active region 104 that are not covered by the gate structure 110 and the gate spacers 120 serve as the source/drain regions 106. In some embodiments, the source/drain regions 106 of p-type transistors, for example, the pull-up transistors PU-1, PU-2 are formed by implanting the portions of the active region 104 that are not covered by the gate structure 110 and the gate spacers 120 with a p-type impurity such as boron, indium, or the like. In some embodiments, the source/drain regions 106 of n-type transistors, for example, the pass-gate transistors PG-1, PG-2, the pull-down transistors PD-1, PD-2 are formed by implanting the portions of the active region 104 that are not covered by the gate structure 110 and the gate spacers 120 with an n-type impurity such as phosphorous, arsenic, antimony, or the like.

In some embodiments, the source/drain regions 106 are formed by etching portions of the active regions 104 that are not covered by the gate structure 110 and the gate spacers 120 to form recesses, and growing epitaxial features in the recesses. The epitaxial features may be formed of Si, Ge, SiP, SiC, SiPC, SiGe, SiAs, InAs, InGaAs, InSb, GaAs, GaSb, InAlP, InP, C, or a combination thereof. Accordingly, the source/drain regions 106 may be formed of silicon germanium (SiGe) in some exemplary embodiments, while the remaining active region 104 may be formed of silicon. In some embodiments, p-type impurities are in-situ doped in the source/drain regions 106 during the epitaxial growth of the source/drain regions 106 of p-type transistors, for example, the pull-up transistors PU-1, PU-2. In addition, n-type impurities are in-situ doped in the source/drain regions 106 during the epitaxial growth of the source/drain regions 106 of n-type transistors, for example, the pass-gate transistor PG-1, PG-2, the pull-down transistors PD-1, PD-2.

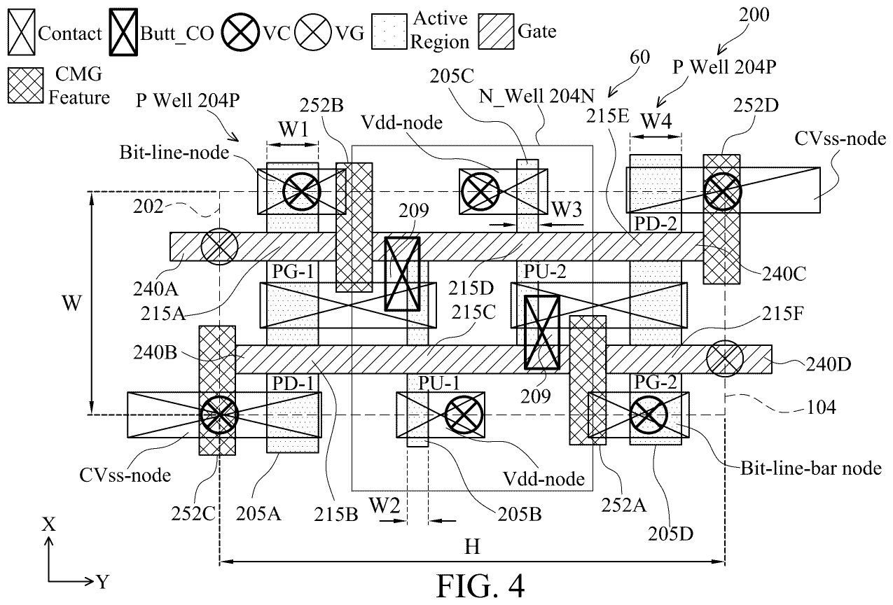

FIG. 4 illustrates an exemplary layout 200 of the SRAM cell 60 as in FIG. 2. A boundary of the SRAM cell 60 is illustrated in FIG. 4 using a rectangular box 202 with dotted lines. The rectangular box 202 is longer in the Y-direction than in the X-direction, for example, about 3.5 times to about 6 times longer. The first dimension of the rectangular box 202 along the X-direction is denoted as a cell width W, and the second dimension of the rectangular box 202 along the Y-direction is denoted as a cell height H. Where the SRAM cell 60 is repeated in a memory array, the cell width W may represent and be referred to as a memory cell pitch in the memory array along the X-direction, and the cell height H may represent and be referred to as a memory cell pitch in the memory array along the Y-direction. In the illustrated embodiment, the cell width W is two times a poly pitch. A poly pitch refers to a minimum center-to-center distance between two adjacent gate structures along the X-direction.

The SRAM cell 60 includes active regions 205 (including 205A, 205B, 205C, and 205D) that are oriented lengthwise along the X-direction, and gate structures 240 (including 240A, 240B, 240C and 240D) that are oriented lengthwise along the Y-direction perpendicular to the X-direction. The active regions 205B and 205C are disposed over an n-type well (or n-well) 204N. The active regions 205A and 205D are disposed over p-type wells (or p-wells) 204P that are on both sides of the n-well 204N along the Y-direction. The gate structures 240 engage the channel regions of the respective active regions 205 to form transistors. In that regard, the gate structure 240A engages the channel region 215A of the active region 205A to form an n-type transistor as the pass-gate transistor PG-1; the gate structure 240B engages the channel region 215B of the active region 205A to form an n-type transistor as the pull-down transistor PD-1 and engages the channel region 215C of the active region 205B to form a p-type transistor as the pull-up transistor PU-1; the gate structure 240C engages the channel region 215E of the active region 205D to form an n-type transistor as the pull-down transistor PD-2 and engages the channel region 215D of the active region 205C to form a p-type transistor as the pull-up transistor PU-2; and the gate structure 240D engages the channel region 215F of the active region 205D to form an n-type transistor as the pass-gate transistor PG-2. In the present embodiment, each of the channel regions 215A-F is in the form of vertically-stacked nanostructures and each of the transistors PU-1, PU-2, PD-1, PD-2, PG-1, and PG-2 is a GAA transistor. Alternatively, each of the channel regions 215A-F is in the form of a fin and each of the transistors PU-1, PU-2, PD-1, PD-2, PG-1, and PG-2 is a FinFET transistor.

Different active regions in different transistors of the SRAM cell 60 may have different widths (e.g., dimensions measured in the Y-direction) in order to optimize device performance. In more detail, the active region 205A of the pull-down transistor PD-1 and the pass-gate transistor PG-1 has a width W1, the active region 205B of the pull-up transistor PU-1 has a width W2, the active region 205C of the pull-up transistor PU-2 has a width W3, and the active region 205D of the pass-gate PG-2 and the pull-down transistor PD-2 has a width W4. The widths W1-W4 may also be measured in portions of the active regions corresponding to the channel regions 215A-F. In other words, these portions of the active regions (from which the widths W1-W4 are measured) are the channel regions (e.g., the vertically-stacked nanostructures of GAA devices) of the transistors. To optimize SRAM performance, in some embodiments, either of the widths W1 and W4 is configured to be greater than either of the widths W2 and W3, as an effort to balance the speed among the n-type transistors and the p-type transistors. For example, a ratio of W1/W2 (or W4/W3) may range from about 1.2 to about 3. In furtherance of some embodiments, the widths W2 and W3 may be the same, and the widths W1 and W4 may be the same.

Still referring to FIG. 4, the SRAM cell 60 further includes source/drain contacts disposed over the source/drain regions of the active regions 205 (the source/drain regions are disposed on both sides of the respective channel region), a butted contact (Butt_Co) 209 disposed over and connecting the active region 205B and the gate structure 240C, another butted contact 409 disposed over and connecting the active region 205C and the gate structure 240B, source/drain contact vias (“VC”) disposed over and connecting to the source/drain contacts, and two gate vias (“VG”) disposed over and connecting to the gate structures 240A and 240D respectively. As the source/drain contact vias VC and the gate vias VG are usually formed in via zero layer (V0 level) of a multilayer interconnect (MLI) disposed over the device layer (in which the active regions and the gate structures are formed), the vias VC and VG are also collectively referred to as vias “V0” in the context. FIG. 4 further illustrates the circuit nodes Vss-node, Vdd-node, Bit-line-node, and Bit-line-bar-node (or BLB node), corresponding to the circuit nodes Vss, Vdd, BL, and BLB in FIG. 2. The bit-line-bar is also referred to as the complementary bit line or the inverse bit line. Also as illustrated in FIG. 4, in the layout 200, the source/drain contact vias VC and the gate vias VG may be positioned on the boundary of the SRAM cell 60 (e.g., positioned on the dotted lines of the rectangular box 202), as the source/drain contact vias VC and the gate vias VG may be shared by adjacent SRAM cells to electrically couple the respective same signal lines together.

Still referring to FIG. 4, the SRAM cell 60 further includes a plurality of gate-cut dielectric features extending lengthwise along the X-direction, including dielectric features 252A, 252B, 252C, 252D (collectively, dielectric features 252). In the illustrated embodiment, the dielectric feature 252A is disposed between the active regions 205C, 205D and abuts the gate structure 240B and the gate structure 240D. The dielectric feature 252A divides an otherwise continuous gate structure into two isolated segments corresponding to the gate structure 240B and the gate structure 240D. Similarly, the dielectric feature 252B is disposed between the active regions 205A, 205B and abuts the gate structure 240A and the gate structure 240C. The dielectric feature 252B divides an otherwise continuous gate structure into two isolated segments corresponding to the gate structure 240A and the gate structure 240C. The dielectric feature 252C is disposed between the active region 205A and the active region in an adjacent SRAM cell to the left of the SRAM cell 60 and separates the gate structure 240B from the gate structure in the adjacent SRAM cell. Similarly, the dielectric feature 252D is disposed between the active region 205D and the active region in an adjacent SRAM cell to the right of the SRAM cell 60 and separates the gate structure 240C from the gate structure in the adjacent SRAM cell. Each of the dielectric features 252 is formed by filling a corresponding cut-metal-gate (CMG) trench in the position of the dielectric features. The dielectric features 252 are also referred to as CMG features. In the illustrated embodiment, each of the dielectric features 252A, 252B is disposed above an interface between the n-well 204N and the respective p-well 204P, and the dielectric features 252C, 252D are disposed above the respective p-well 204P.

A CMG process refers to a fabrication process where after a metal gate (e.g., a high-k metal gate or HKMG) replaces a dummy gate structure (e.g., a polysilicon gate), the metal gate is cut (e.g., by an etching process) to separate the metal gate into two or more gate segments. Each gate segment functions as a metal gate for an individual transistor. An isolation material is subsequently filled into trenches between adjacent portions of the metal gate. These trenches are referred to as cut-metal-gate trenches, or CMG trenches, in the present disclosure. The dielectric material filling a CMG trench for isolation is referred to as a CMG feature. To ensure a metal gate would be completely cut, a CMG feature often further extends into adjacent areas, such as dielectric layers filling space between the metal gates. A CMG feature often have an elongated shape in a top view. For example, as shown in FIG. 4, each of the CMG features 252 has an elongated shape extending lengthwise in the X-direction.

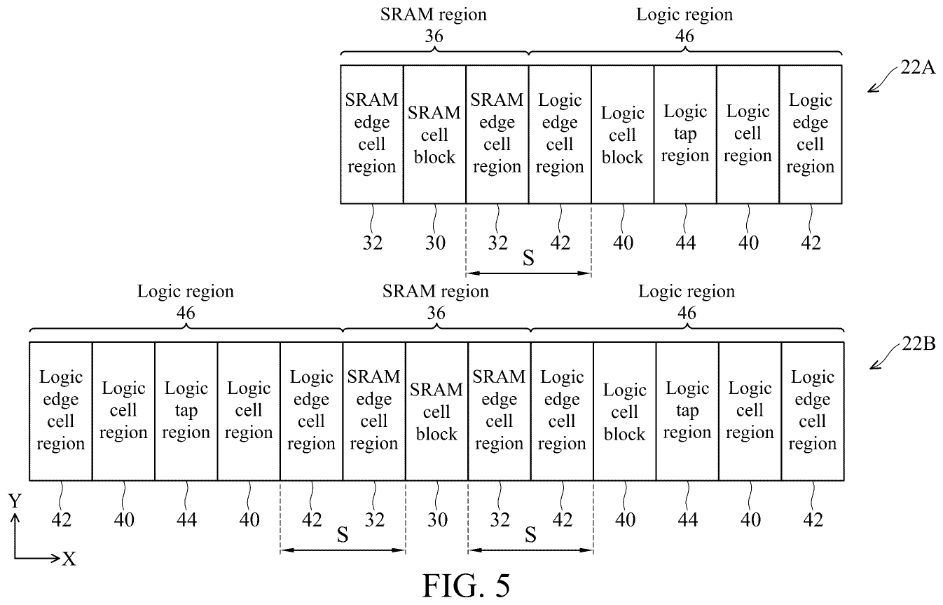

FIG. 5 illustrates simplified block diagrams of a portion of the circuit region 22 as in FIG. 1. Particularly, the block diagram 22A represents a simplified top view of a portion of the circuit region 22, in accordance with some embodiments of the present disclosure, and the block diagram 22B represents a simplified top view of a portion of the circuit region 22, in accordance with some other embodiments of the present disclosure. The circuit region 22 may be implemented with one of the block diagrams 22A, 22B based on circuit performance needs, but free of another. Alternatively, the circuit region 22 may be implemented with both block diagrams 22A, 22B with each at a different portion of the circuit region 22. FIG. 5 has been simplified for the sake of clarity to better understand the inventive concepts of the present disclosure. Additional features can be added in the block diagrams 22A, 22B, and some of the features described below can be replaced, modified, or eliminated in other embodiments of the block diagrams 22A, 22B.

In the illustrated embodiment, the memory cell block 30 is an SRACM cell block that includes at least one SRAM cell. Accordingly, the memory cell block 30 is also referred to as the SRAM cell block. Generally, the SRAM cell block 30 may include multiple SRAM cells, such as the SRAM cell 60 in FIG. 2, arranged in rows and columns of an array. Two SRAM edge cell regions 32 abut the opposing edges of the SRAM cell block 30 along the X-direction, respectively. An SRAM edge cell region 32 is configured with edge cells, such as dummy cells and/or well strap cells, to facilitate uniformity in fabrication and/or performance of SRAM cells in the SRAM cell block 30. Dummy cells are configured physically and/or structurally similar to an SRAM cell, such as the SRAM cell 60 in FIG. 2, but do not store data. For example, dummy cells can include p-type wells, n-type wells, channels (e.g., formed in one or more fins or one or more suspended channel layers (e.g., nanowires or nanosheets)), gate structures, source/drains, and/or interconnects (e.g., contacts, vias, and/or metal lines). Well strap cells generally refer to non-functional cells that are configured to electrically connect a voltage to an n-well of the SRAM cells, a p-well of the SRAM cells, or both. For example, an n-type well strap is configured to electrically couple an n-well that corresponds with at least one p-type transistor of an SRAM cell to a voltage source, and a p-type well strap is configured to electrically couple a p-well that corresponds with at least one n-type transistor of an SRAM cell to a voltage source.

In the illustrated embodiment, the logic cell block 40 includes at least one logic cell. Generally, the logic cell block 40 may include multiple logic cells to provide read operations and/or write operations to the SRAM cells in the SRAM cell block 30. A logic tap region 44 is positioned between two adjacent logic cell blocks 40 along the X-direction. The logic tap region 44 includes tap cells similar to the well strap cells discussed above. The tap cells may take shape of a transistor in the logic cell block 40 but they do not have functional gate structures. The tap cells may be implemented to couple certain wells to proper voltage sources. For example, an n-type tap cell is configured to electrically couple an n-well that corresponds with at least one p-type transistor of a logic cell to a voltage source, and a p-type well strap is configured to electrically couple a p-well that corresponds with at least one n-type transistor of a logic cell to a voltage source. A logic edge cell region 42 is positioned between an SRAM edge cell region 32 and a logic cell block 40. The logic edge cell region 42 abuts an edge of the SRAM edge cell region facing the logic cell block 40 and an opposing edge of the logic cell block 40 facing the SRAM edge cell region 32. The logic edge cell region 42 is configured with dummy cells to facilitate uniformity in fabrication and/or performance of logic cells in the logic cell block 40. The dummy cells may take shape of a transistor in the logic cell block 40 but they do not have functional gate structures. As shown in the block diagram 22A, a combination that comprises a first logic cell block 40, a logic tap region 44, and a second logic cell region 40 may be sandwiched by two logic edge cell regions 42. In the block diagram 22A, the SRAM edge cell region 32 and the abutting logic edge cell region 42 collectively define a reserved space spanning a distance S between the SRAM cell block 30 and the logic cell block 40.

For clarity and simplicity, similar features in the block diagram 22B are identified by the same reference numerals as in the block diagram 22A, and such similar aspects are not repeated. One difference between the block diagrams 22A and 22B is that the logic-related circuits (e.g., blocks and/or regions 40, 42, 44 devoted to logic functions, collectively referred to as logic region 46) are disposed on one side of the memory-related circuits (e.g., blocks and/or regions 30, 32 devoted to memory functions, collectively referred to as memory region 36) in the block diagram 22A, but on both sides in the block diagram 22B. The placement of the logic-related circuits on one side or both sides of the memory-related circuits is determined by predefined design rules and/or circuit performance needs. In either of the block diagrams 22A and 22B, the SRAM region 36 and the logic region 46 each have own edge cell regions, and the SRAM cells and logic cells are hard to directly abut. A distance S between the boundaries of the SRAM cell block 30 and the logic cell block 40 to spare a reserved space for hosting the SRAM edge cell region 32 and the logic edge cell region 42 take up an undue amount of real estate in a macro.

This is so because although well strap cells in the SRAM edge cell region 32 may be formed in the same active regions as the SRAM cells in the SRAM cell block 30, the different doping types prevent them from being placed right next to each other. For example, the n-wells and p-wells in the SRAM region 36 may extend along the same direction from the SRAM cell block 30 into the SRAM edge cell region 32, each have an elongated shape, and are alternately arranged. Fins or vertical stacks of channel layers may be formed over the n-wells or the p-wells and doped with different types of dopants. However, when an active region of the well strap cells abuts an active region of a different conductivity type of the memory cells, it gives rise drift of electrical characteristics of the memory cells and deteriorated performance. To isolate a well strap cell from an adjacent memory cell, discontinuations of the active regions are introduced. As discussed above, because the active regions are sometimes disposed in and defined by a silicon-oxide containing isolation feature (such as a shallow trench isolation, or STI), the active regions may be referred to as oxide-definition regions or “ODs”, and the discontinuations of the active regions may be referred to as OD breaks. In some embodiments, OD breaks are formed before the deposition of the isolation feature and the formation of the source/drain features. Because the OD breaks are formed before the deposition of the isolation feature, the material for the isolation feature is also deposited in the OD breaks. Because the OD breaks are formed before the formation of the source/drain features that exert stress on the active region, the active regions adjacent to the OD breaks are exposed to different environment and may have different properties. The OD breaks therefore also bring about a form of layout dependent effect where the active region of the standard cell is broken by another active region of the well strap cells.

To address the layout dependent effect brought about by the OD breaks, dummy cells may be introduced between the SRAM cells and the OD breaks to serve as a transition between an OD break and the SRAM cells. In one example, the SRAM edge cell region 32 may have a width of 10 poly pitches measured in the X-direction. Among the 10 poly pitches, 4 poly pitches are devoted for well strap cells, and 6 poly pitches are for dummy cells, with OD breaks between the well strap cells and the dummy cells. Additionally, the logic edge cell region 42 may have a width of 2.5 poly pitches devoted to dummy cells for the logic cells, with OD breaks between the well strap cells in the SRAM edge cell region 32 and the logic edge cell region 42. Thus, a distance S between the boundaries of the SRAM cell block 30 and the logic cell block 40 to spare a reserved space for hosting the SRAM edge cell region 32 and the logic edge cell region 42 is 12.5 poly pitches. Considering an SRAM cell 60 as in FIG. 4 has a cell width of 2 poly pitches, the reserved space between the SRAM cell block 30 and the logic cell block 40 takes a region that could have filled 5 or 6 extra columns of SRAM cells, which results in a significant increase in the overall device size. In light of the foregoing, it can be seen that for the SRAM cell block 30 to have its own well strap cells and associated extra dummy cells as isolation structures between the SRAM cells and well strap cells can take up an undue amount of real estate in a macro.

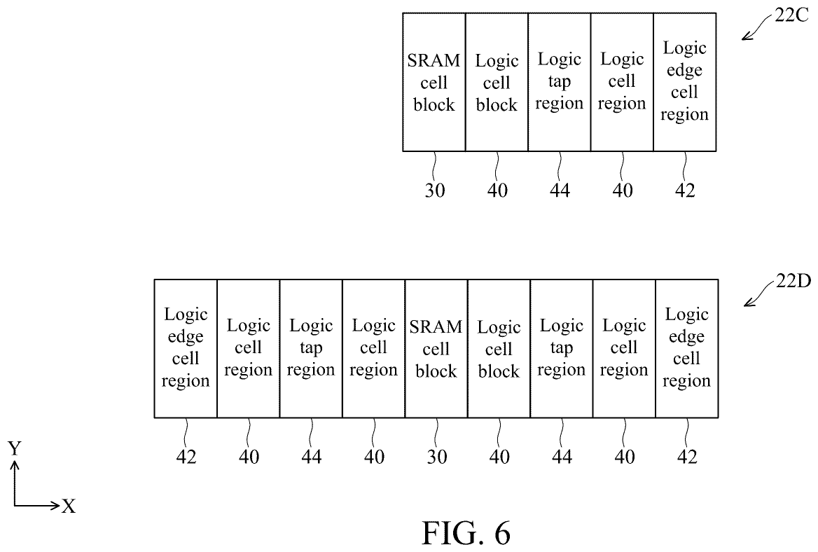

Reference now is made to FIG. 6. FIG. 6 illustrates simplified block diagrams 22C, 22D of a portion of the circuit region 22 as in FIG. 1, which are alternative embodiments with respect to the ones (22A, 22B) in FIG. 5. The circuit region 22 may be implemented with one of the block diagrams 22C, 22D based on circuit performance needs, but free of another. Alternatively, the circuit region 22 may be implemented with both block diagrams 22C, 22D with each at a different portion of the circuit region 22. FIG. 6 has been simplified for the sake of clarity to better understand the inventive concepts of the present disclosure. Additional features can be added in the block diagrams 22C, 22D, and some of the features described below can be replaced, modified, or eliminated in other embodiments of the block diagrams 22C, 22D.

For clarity and simplicity, similar features in the block diagrams 22C, 22D are identified by the same reference numerals as in the block diagrams 22A, 22B, and such similar aspects are not repeated. One difference between the block diagrams 22C, 22D and the block diagrams 22A, 22B is that the SRAM cell block 30 abuts the logic cell block 40 with no SRAM edge cell region 32 and logic edge cell region 42 therebetween. In the block diagram 22C, the logic-related circuits are disposed on a single side of the SRAM cell block 30. In the block diagram 22D, the logic-related circuits are disposed on both sides of the SRAM cell block 30. The placement of the logic-related circuits on one side or both sides of the memory-related circuits is determined by predefined design rules and/or circuit performance needs.

As the n-wells and p-wells in the SRAM cell block 30 also extend into the logic cell block 40 and the logic tap region 44, the tap cells in the logic tap region 44 may be configured to provide potential stability to wells for not only the logic cell block 40 but also the SRAM cell block 30. Therefore, the well strap cells may not be separately needed for the SRAM cell block 30, and dummy cells as isolation structures between the SRAM cells and the OD breaks associated with the well strap cells may not be further needed. Accordingly, the whole SRAM edge cell region 32 may be spared. Further, the dummy cells in the logic edge cell region 42 as isolation structures between the logic cells and the OD breaks associated with the well strap cells may not be further needed, and the logic edge cell region 42 originally abutting the SRAM edge cell region 32 may be spared as well. State differently, by sharing the function of the tap cells in the logic region between the SRAM cell block 30 and the logic cell block 40, the SRAM cell block 30 and the logic cell block 40 may directly abut each other without the SRAM edge cell region 32 and the logic edge cell region 42 therebetween. As a result, the utilization of real estate in a macro is significantly improved. In some embodiments, a reduction above 40% of the macro area may be achieved.

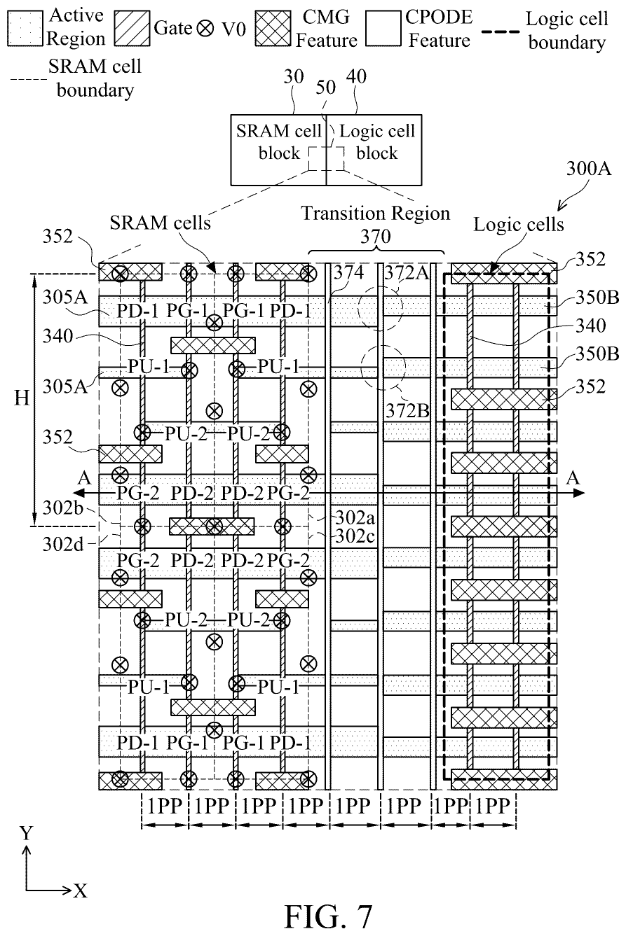

FIG. 7 illustrates a layout 300A of a circuit region 50 of the block diagram 22C and/or the block diagram 22D in FIG. 6 according to the present disclosure, which includes a portion of the SRAM cell block 30 and a portion of the logic cell block 40 and extends across an interface between the SRAM cell block 30 and the logic cell block 40. FIG. 7 has been simplified for the sake of clarity to better understand the inventive concepts of the present disclosure. For example, active regions, gate structures, gate-cut features, and vias V0 in the SRAM cells are shown, while some other features are omitted in FIG. 7.

The circuit region 50 includes a first type of active regions 305A in the SRAM cell block 30 and a second type of active regions 305B in the logic cell block 40 (collectively as active regions 305). The active regions 305A are arranged along the Y-direction and oriented lengthwise in the X-direction. As discussed above, the active regions 305A may have different widths (e.g., W1-W4 in FIG. 4). The active regions 305B are arranged along the Y-direction and oriented lengthwise in the X-direction. In the illustrated embodiment, the active regions 305B are evenly distributed along the Y-direction and each have a uniform width. The circuit region 50 further includes gate structures 340 arranged along the X-direction and extending lengthwise in the Y-direction. In the illustrated embodiment, the gate structures 340 are evenly distributed along the X-direction with a uniform distance between two adjacent gate structures 340. The uniform distance is denoted as a gate pitch or a poly pitch (“PP”). Gate-cut features, particularly the CMG features 352, divide the otherwise continuous gate structures into isolated segments corresponding to the gate structures 340 as depicted. The gate structures 340 intersect the active regions 305A, 305B in forming transistors. Transistors formed at the intersections of the active regions 305A and the gate structures 340 are within the SRAM cell block 30 and devoted to form SRAM cells. The transistors formed at the intersections of the active regions 305B and the gate structures 340 are within the logic cell block 40 and devoted to form logic cells.

In the illustrated embodiment, the transistors in the SRAM cell block 30 form a plurality of SRAM cells 302a, 302b, 302c, and 302d (collectively, SRAM cells 302). The SRAM cells 302 are arranged in the X-direction and the Y-direction, forming a 2×2 array of SRAM cells. Each SRAM cell 302 in the array may use the layout 200 of the SRAM cell 60 as depicted in FIG. 4. In some embodiments, two adjacent SRAM cells in the X-direction are line symmetric with respect to a common boundary therebetween, and two adjacent SRAM cells in the Y-direction are line symmetric with respect to a common boundary therebetween. That is, the SRAM cell 302b is a duplicate cell for the SRAM cell 302a but flipped over the Y-axis; the SRAM cell 302c is a duplicate cell for the SRAM cell 302a but flipped over the X-axis; and the SRAM cell 302d is a duplicate cell for the SRAM cell 302b but flipped over the X-axis.

Some active regions 305 extend through multiple SRAM cells in a row. For example, the active region for the transistors PD-1, PG-1 in the SRAM cell 302b extends through the SRAM cell 304a as the active region for its transistors PG-1, PD-1; the active region for the transistors PG-2, PD-2 in the SRAM cell 302b extends through the SRAM cell 302a as the active region for its transistors PD-2, PG-2; and the active region for the transistors PU-2 in the SRAM cell 302b extends into the SRAM cell 302a as the active region for its transistors PU-2. The active regions in the SRAM cells 302c, 302d are similarly arranged.

In the illustrated embodiment, the transistors in the logic cell block 40 form a plurality of logic cells. The logic cells may be standard cells, such as inventor (INV), AND, OR, NAND, NOR, Flip-flip, SCAN and so on. The logic cells implement various logic functions to the SRAM cells 302. The logic functions of the logic cells include, for example, write and/or read decoding, word line selecting, bit line selecting, data driving and memory self-testing.

Between the opposing boundary lines of the SRAM cells and the logic cells is an active region transition region 370, also referred to as the OD transition region or simply as the transition region. Inside the transition region 370, the active regions 305A extending from the edge column of the SRAM cells meet the active regions 305B extending from the edge column of the logic cells. Since a pair of the active regions 305A, 305B that meet may have different widths, an OD jog is created at where the active regions 305A, 305B meet. A jog refers to a junction where two segments of different widths meet each other. For example, in the region 372A represented by a dotted circle, a relatively wide active region 305A meets a relatively narrow active region 305B, creating an OD jog. The upper edges of the active regions 305A, 305B align, while the lower edges of the active regions 305A, 305B creates a step profile. Similarly, in the region 372B represented by another dotted circle, a relatively narrow active region 305A meets a relatively wide active region 305B, creating another OD job. The lower edges of the active regions 305A, 305B align, while the upper edges of the active regions 305A, 305B creates a step profile.

As depicted in the layout 300A, the transition region 370 has a span of three poly pitches between the opposing boundary lines of the SRAM cells and the logic cells along the X-direction. In the transition region 370, a plurality of dielectric features 374 are arranged along the X-direction and oriented lengthwise in the Y-direction. The dielectric features 374 provide isolation between the active regions 305A and 305B. In the layout 300A, the dielectric features 374 continuously extend along the boundary lines of the SRAM cells and the logic cells in the Y-direction. In other words, the dielectric features 374 are taller the SRAM cell height H. In the layout 300A, the dielectric features 374 are at least taller than 2 times the SRAM cell height H. In some embodiments, the SRAM array has about 100,000 SRAM cells in a column, and the dielectric features 374 may extend continuously in the Y-direction along the boundary line of the edge column. That is, a ratio of the length of the dielectric features 374 and the SRAM cell height H may be as large as about 100,000:1. A length of the dielectric features 374 measured in micrometer (um) may be as large as about 150 um in some embodiments.

The dielectric features 374 are formed in a continuous-poly-on-diffusion-edge (CPODE) process. In a CPODE process, a polysilicon gate is replaced by a dielectric feature. For purposes of this disclosure, a “diffusion edge” may be equivalently referred to as an active edge, where for example an active edge abuts adjacent active regions. Before the CPODE process, the active edge may include a dummy GAA structure having a dummy gate structure (e.g., a polysilicon gate) and a plurality of vertically stacked nanostructures as channel layers. In addition, inner spacers may be disposed between adjacent nanostructures at lateral ends of the nanostructures. In various examples, source/drain epitaxial features are disposed on either side of the dummy GAA structure, such that the adjacent source/drain epitaxial features are in contact with the inner spacers and nanostructures of the dummy GAA structure. The subsequent CPODE etching process removes the dummy gate structure and the channel layers from the dummy GAA structure to form a CPODE trench. The dielectric material filling a CPODE trench for isolation is referred to as a CPODE feature. In some embodiments, after the CPODE features are formed, the remaining dummy gate structures are replaced by metal gate structures in a replacement gate (gate-last) process. State differently, in some embodiments, the CPODE feature replaces a portion or full of the otherwise continuous gate structure and is confined between the opposing gate spacers of the replaced portion of the gate structure. As a comparison, the CMG feature truncates the otherwise continuous gate structure and extends into adjacent areas of the gate structure. Accordingly, in the layout 300A, the circuit region 50 includes two types of gate-cut features. The first gate-cut features are the CMG features 352, which are disposed in the SRAM cells or logic cells, but not in the transition region 370, in the illustrated embodiment. The CMG features 352 extend lengthwise along the X-direction. The second gate-cut features are the CPODE features 374, which are disposed in the transition region 370. The CPODE features 374 extend lengthwise along the Y-direction.

Since the CPODE features 374 are formed by replacing the previously-formed polysilicon gate structures, the CPODE features 374 inherit the arrangement of the gate structures 340. That is, the CPODE features 374 may have the same width as the gate structures 340 and the same pitch as the gate structures 340. As depicted in the layout 300A, since the transition region 370 has a span of three poly pitches and has three polysilicon gate previously disposed therein prior to the CPODE process, there are three CPODE features 374 disposed in the transition region 370 after the CPODE process. The left-most CPODE feature 374 abuts the active regions 305A, the right-most CPODE feature 374 abuts the active regions 305B. The segments of the active regions 305A and 305B sandwiched between the left-most and right-most CPODE features 374 are actually separated from the main portions of the active regions 305A, 305B, and can be considered as dummy active regions, or dummy ODs. The three CPODE features 374 sandwich two segments of the dummy ODs from the same row, one from the end of the active region 305A and another from the end of the active region 305B. The two segments of the dummy ODs may also be considered as the OD jog.

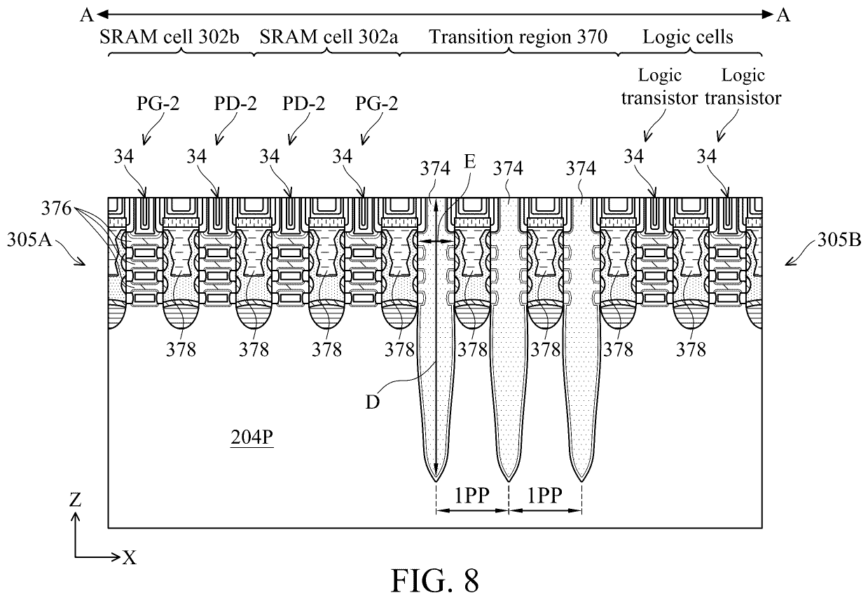

FIG. 8 is a fragmentary diagrammatic cross-sectional view along A-A line of FIG. 7, which cuts a pair of the active regions 305A and 305B. The active region 305A extends continuously through the SRAM cells 302a, 302b (and other SRAM cells in the same row of a memory array). The active region 305B extends continuously through the logic cells in the same row of a logic array. The active regions 305A, 305B are disposed on a same continuous p-well, which extends across the SRAM cell block 30, the logic cell block 40, and the logic tap region 44 (FIG. 6) and is biased to a supply voltage by the tap cells in the logic tap region 44. In other words, the tap cells in the logic tap region 44 also bias the wells for the SRAM cells in the SRAM cell block 30. Each of the active regions 305A, 305B include channel regions that are comprised of the nanostructures 376 and source/drain features 378 abutting the ends of the nanostructures 376. The gate structures 340 wrap around the nanostructures 26 and form the transistors PG-2, PD-2 in the SRAM cell 302b, the transistors PD-2, PG-2 in the SRAM cell 302a, and the logic transistors in the logic cells. The CPODE features 374 replace otherwise three gate structures 340 in the row. Source/drain features 378 are also disposed on sidewalls of the CPODE feature 374. Also as shown in the cross-sectional view, the CPODE feature has a width denoted as E and a depth denoted as D. In some embodiments, the CPODE width E ranges from about 15 nm to about 20 nm; the CPODE depth D ranges from about 150 nm to about 250 nm. If the depth D is smaller than about 150 nm, the isolation performance may be compromised; if the depth D is larger than about 250 nm, the CPODE feature 374 may extend too deep into the well (e.g., the p-well 204P in FIG. 8) and the biasing from the tap cells in the logic region may be insufficient to bias the well in the SRAM region. The CPODE features 374 may extend downwardly deeper than the CMG features 352. Also as shown in the cross-sectional view, there is no OD breaks in the transition region 370.

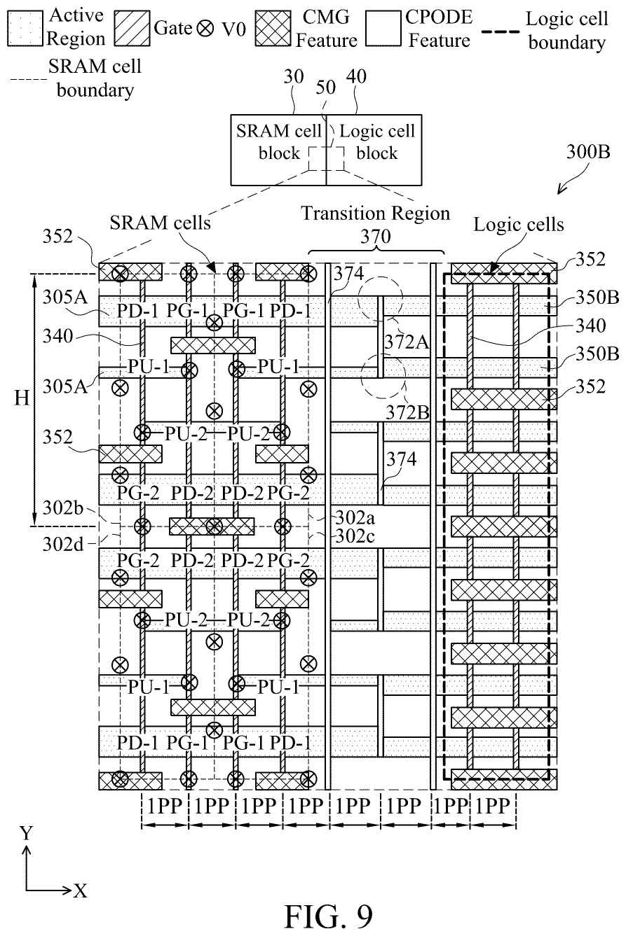

FIG. 7 depicts all the CPODE features 374 as continuous lines, while the CPODE features 374 may be continuous lines or in the form of islands in various embodiments. FIG. 9 illustrates a layout 300B of the circuit region 50, in which at least some of the CPODE features are in the form of islands. Referring to FIG. 9, for clarity and simplicity, similar features in the layouts 300A and 300B are identified by the same reference numerals, and such similar aspects are not repeated. One difference between the layouts 300A and 300B is that the middle CPODE features are not a continuous line in the layout 300b but multiple islands spread in the Y-direction. Each middle CPODE feature 374 is extending lengthwise along the Y-direction and separates at least one pair of the active regions 305A, 305B at the OD jog. In the illustrated embodiment in FIG. 9, each middle CPODE feature 374 separates two pairs of the active regions 305A, 305B. A length of the middle CPODE feature 374 measured in the Y-direction may be at least 5 nm in some embodiments. A length of the middle CPODE feature 374 may be less than the SRAM cell height H, or even less than half of the SRAM cell height H.

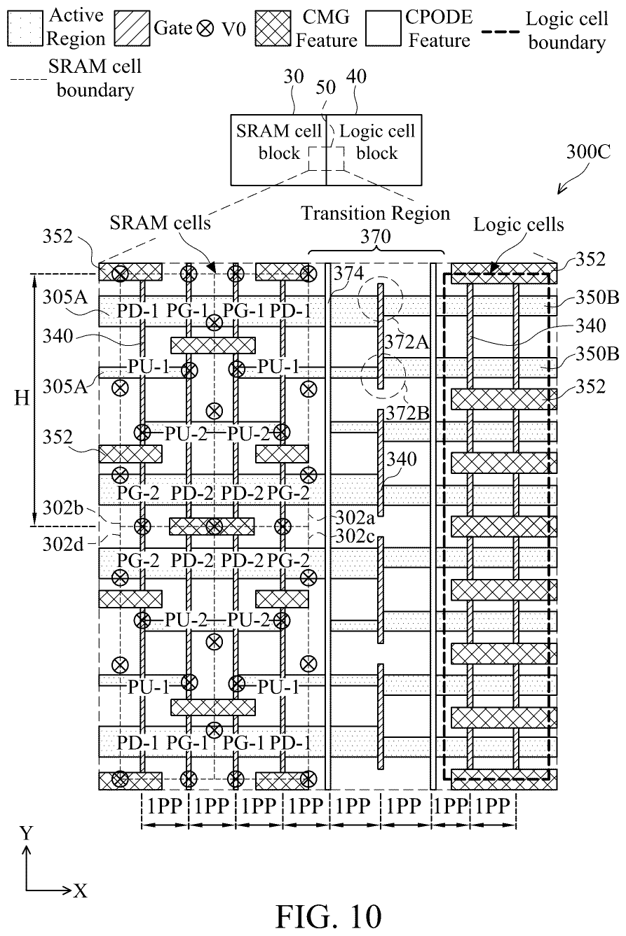

FIG. 7 depicts that all the gate structures in the transition region 370 are replaced by the CPODE features 374, while some gate structures in the transition region 370 may remain in various embodiments. FIG. 10 illustrates a layout 300C of the circuit region 50, in which at least some of the gate structures 340 remain in the transition region 370. Referring to FIG. 10, for clarity and simplicity, similar features in the layouts 300A and 300C are identified by the same reference numerals, and such similar aspects are not repeated. One difference between the layouts 300A and 300C is that the gate structures 340 between the left-most CPODE feature 374 and the right-most CPODE feature 374 remain in the layout 300C. The remaining gate structures 340 are disposed over the OD jogs. The isolation between the active regions 305A, 305B is provided by two CPODE features 374. As a comparison, the isolation between the active regions 305A, 305B is provided by three CPODE features 374 as in either the layout 300A or the layout 300B.

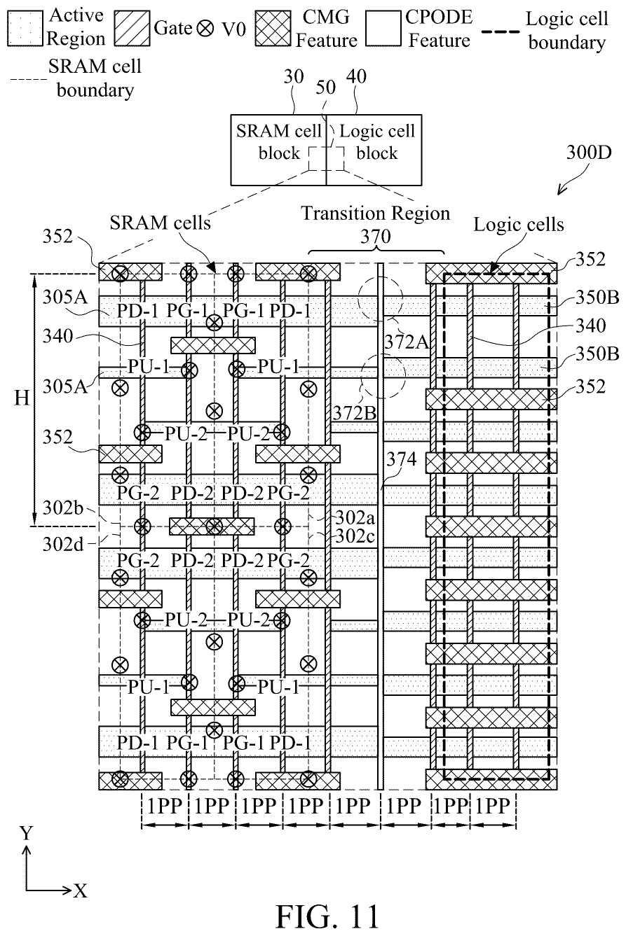

Similarly, FIG. 11 illustrates a layout 300D of the circuit region 50, in which at least some of the gate structures 340 remain in the transition region 370. Referring to FIG. 11, for clarity and simplicity, similar features in the layouts 300A and 300D are identified by the same reference numerals, and such similar aspects are not repeated. One difference between the layouts 300A and 300D is that the gate structures 340 in the left-most column and the right-most column in the transition region 370 remain, sandwich one CPODE feature 374 disposed over the OD jogs. The isolation between the active regions 305A, 305B is provided by the single CPODE feature 374. Notable, in the illustrated embodiment in FIG. 11, the CMG features 352 extend into the transition region 370 to divide the otherwise continuous gate structure lines into segments corresponding the gate structures 340 in the transition region 370. In other words, in such an embodiment, the transition region 370 includes two types of gate-cut features, the CPODE feature 374 and the CMG features 352.

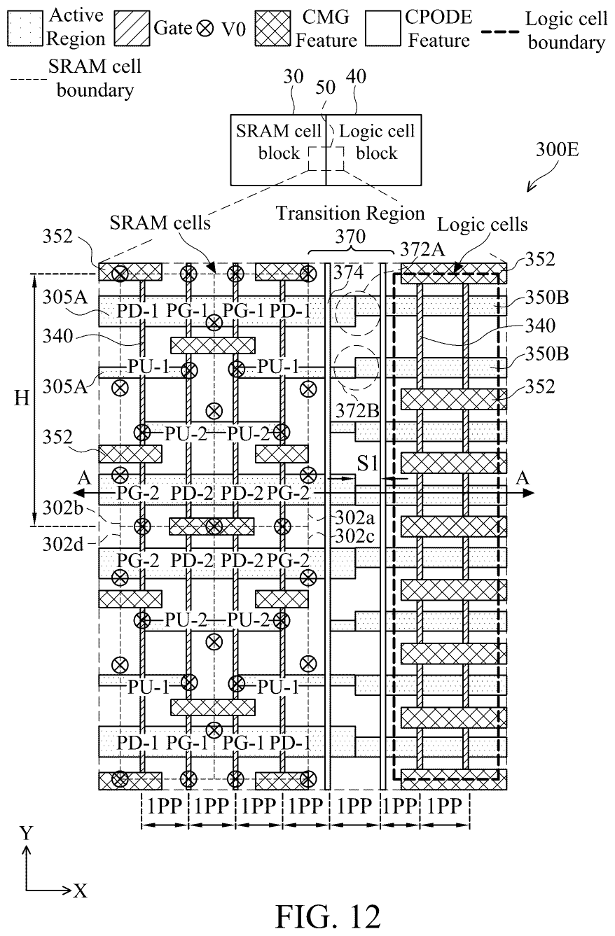

The layouts 300A-300D depict the transition region 370 as spanning in the X-direction three poly pitches, while the transition region 370 may span less than three poly pitches in various embodiments. FIG. 12 illustrates a layout 300E of the circuit region 50, in which the transition region 370 spans in the X-direction two poly pitches. Referring to FIG. 12, for clarity and simplicity, similar features in the layouts 300A and 300E are identified by the same reference numerals, and such similar aspects are not repeated. One difference between the layouts 300A and 300E is that the transition region 370 spans two poly pitches and includes two CPODE features 374 in the layout 300E. The active regions sandwiched by the two CPODE features 374 are considered as dummy ODs with the OD jogs. The OD jogs are between the two CPODE features 374. A distance from the position of the OD jog to one of the CPODE features 374 is denoted as an offset S1. The position of the OD jog does not have to be in the exact middle point of the two CPODE features 374. A ratio of S1 and the poly pitch may range from about 0.1 to about 1. Similar to what is discussed above, the CPODE features 374 can be the form of continuous lines or islands as long as sufficient isolation can be provided. In some embodiments, a length of the CPODE feature 374 measured in the Y-direction ranges from about 0.2 um to about 150 um.

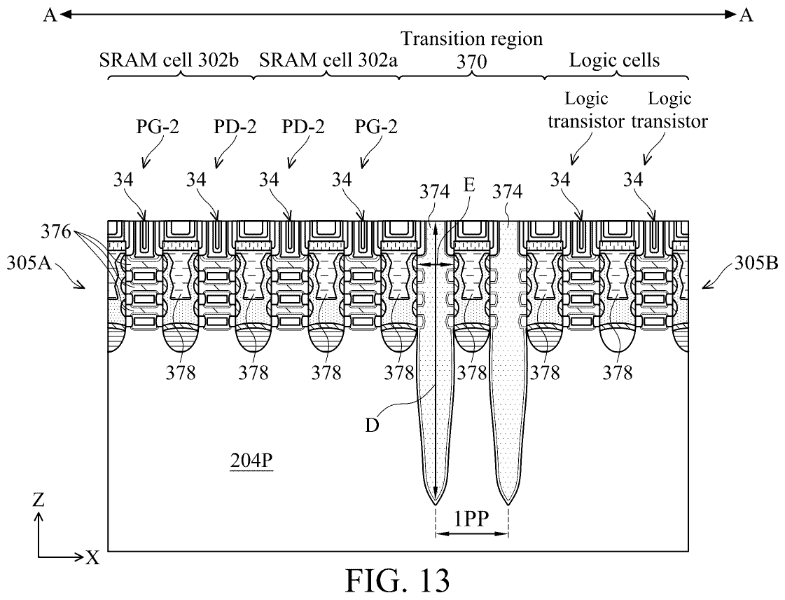

FIG. 13 is a fragmentary diagrammatic cross-sectional view along A-A line of FIG. 12, which cuts a pair of the active regions 305A and 305B. Referring to FIG. 13, for clarity and simplicity, similar features in the FIGS. 8 and 13 are identified by the same reference numerals, and such similar aspects are not repeated. One difference between the cross-sectional views in FIGS. 8 and 13 is that the transition region 370 spans in the X-direction two poly pitches in FIG. 13, which is one less than in FIG. 8, and the transition region 370 includes two CPODE features 374 in FIG. 13, which is one less than in FIG. 8.

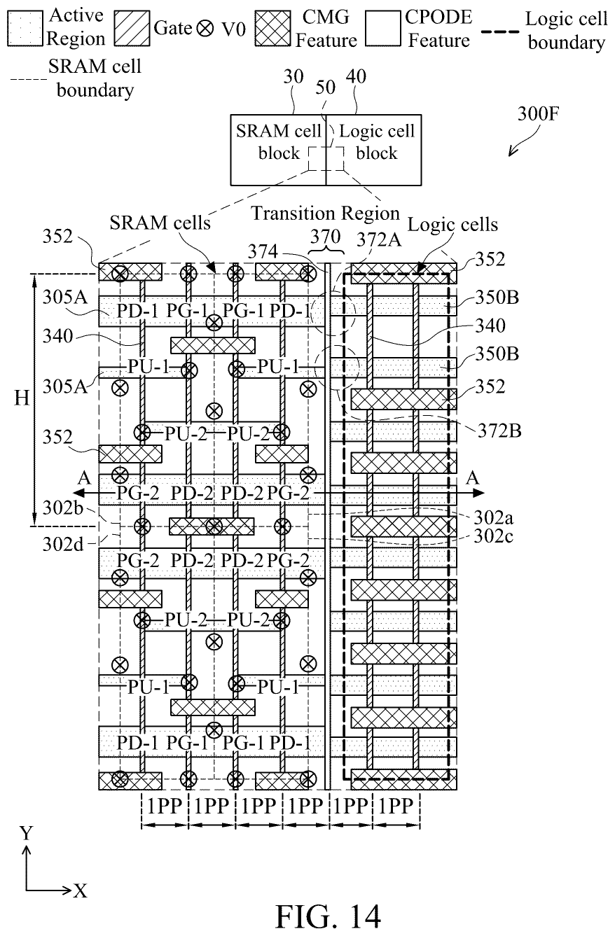

The layouts 300A-300D depict the transition region 370 as spanning in the X-direction three poly pitches, while the transition region 370 may span less than three poly pitches in various embodiments. FIG. 14 illustrates a layout 300F of the circuit region 50, in which the transition region 370 spans in the X-direction one poly pitch. Referring to FIG. 14, for clarity and simplicity, similar features in the layouts 300A and 300F are identified by the same reference numerals, and such similar aspects are not repeated. One difference between the layouts 300A and 300F is that the transition region 370 spans a single poly pitch and includes one CPODE feature 374 in the layout 300F. The single CPODE feature 374 overlaps with the OD jogs. Similar to what is discussed above, the CPODE feature 374 can be the form of a continuous line or islands as long as sufficient isolation can be provided. In some embodiments, a length of the CPODE feature 374 measured in the Y-direction ranges from about 0.2 um to about 150 um.

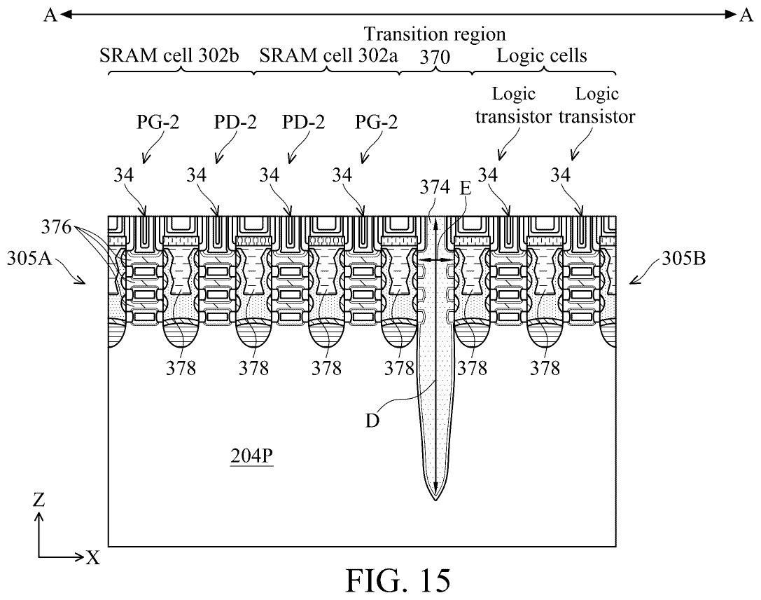

FIG. 15 is a fragmentary diagrammatic cross-sectional view along A-A line of FIG. 14, which cuts a pair of the active regions 305A and 305B. Referring to FIG. 15, for clarity and simplicity, similar features in the FIGS. 8 and 15 are identified by the same reference numerals, and such similar aspects are not repeated. One difference between the cross-sectional views in FIGS. 8 and 15 is that the transition region 370 spans in the X-direction one poly pitch in FIG. 15, which is two less than in FIG. 8, and the transition region 370 includes a single CPODE feature 374 in FIG. 15, which is two less than in FIG. 8. Notable, although various embodiments of the transition region 370 with a spanning (width) of one, two, and three poly pitches are illustrated in the present disclosure, other embodiments contemplate various different numbers of the poly pitches. For example, the transition region 370 may have a width spanning N poly pitches, in which N is an integer, such as 1, 2, 3, 4, 5, 6, and so on.

Based on the above discussions, it can be seen that the present disclosure offers advantages over conventional semiconductor structures. It is understood, however, that other embodiments may offer additional advantages, and not all advantages are necessarily disclosed herein, and that no particular advantage is required for all embodiments. For example, the present disclosure provides a memory macro that allows the memory cell block and the logic cell block to abut by sharing the tap cells for the logic cell block with the memory cell block. Edge cells conventionally inserted between the memory cell block and the logic cell block may not be further needed. A memory macro area may be reduced by over 40% in some embodiments.

In one exemplary aspect, the present disclosure is directed to a semiconductor structure. The semiconductor structure includes a memory cell, a logic cell configured to provide logic function to the memory cell, and a transition region between the memory cell and the logic cell. The memory cell includes at least a first active region extending lengthwise in a first direction and a plurality of first gate structures extending lengthwise in a second direction perpendicular to the first direction and spaced apart from each other in the first direction with a gate pitch. The logic cell includes a second active region extending lengthwise in the first direction and a plurality of second gate structures extending lengthwise in the second direction and spaced apart from each other in the first direction with the gate pitch. The transition region includes a first dielectric feature extending lengthwise in the second direction and a second dielectric feature extending lengthwise in the second direction. The first dielectric feature divides the first active region into a first segment partially in the transition region and a second segment fully in the transition region. The second dielectric feature divides the second active region into a third segment partially in the transition region and a fourth segment fully in the transition region. In some embodiments, the first dielectric feature is spaced apart from one of the first gate structures for the gate pitch. In some embodiments, the second dielectric feature is spaced apart from one of the second gate structures for the gate pitch. In some embodiments, a width of the transition region measured in the first direction is an integer multiple of the gate pitch. In some embodiments, the second segment of the first active region abuts the fourth segment of the second active region. In some embodiments, the transition region includes a plurality of third gate structures, one of the third gate structures is disposed over an interface between the second segment of the first active region and the fourth segment of the second active region. In some embodiments, the transition region includes a third dielectric feature extending lengthwise in the second direction and between the first and second dielectric features. In some embodiments, the third dielectric feature separates the second segment of the first active region from contacting the fourth segment of the second active region. In some embodiments, the third dielectric feature has a length measured in the second direction that is smaller than the first and second dielectric features. In some embodiments, the memory cell includes a gate-cut feature abutting one of the first gate structures and extending lengthwise in the first direction. In some embodiments, the gate-cut feature extends into the transition region.

In another exemplary aspect, the present disclosure is directed to an integrated circuit layout. The integrated circuit layout includes a memory circuit with a first boundary, a logic circuit with a second boundary, and a transition region spanning from an edge of the first boundary to an edge of the second boundary with a width of an integer multiple of the gate pitch. The memory circuit includes a plurality of first active regions, and a plurality of first gate structures across the first active regions, the first gate structures having a gate pitch. The logic circuit includes a plurality of second active regions, and a plurality of second gate structures across the second active regions, the second gate structures having the gate pitch. The transition region includes at least one dielectric feature separating the first active regions from contacting the second active regions. In some embodiments, the transition region has the width of one gate pitch, and the at least one dielectric feature has a first sidewall contacting the first active regions and a second sidewall contacting the second active regions. In some embodiments, the transition region has the width of two gate pitches, and the transition region includes first and second dielectric features that are spaced apart for one gate pitch. In some embodiments, the transition region has the width of three gate pitches, and the at least one dielectric feature is located on a center line of the transition region. In some embodiments, the transition region has the width of three gate pitches, and the transition region includes first and second dielectric features that are spaced apart for two gate pitches and a plurality of third gate structures disposed between the first and second dielectric features. In some embodiments, the transition region has the width of three gate pitches, and the transition region includes first, second, and third dielectric features that are spaced apart from adjacent ones for the gate pitch.

In yet another exemplary aspect, the present disclosure is directed to a static random-access memory (SRAM) circuit. The SRAM circuit includes an SRAM cell including a first pass-gate transistor and a first pull-down transistor formed on a first active region and a second pass-gate transistor and a second pull-down transistor formed on a second active region, the first and second active regions extending lengthwise in a first direction, and a dielectric feature extending lengthwise in a second direction perpendicular to the first direction, the dielectric feature having a sidewall in contact with the first active region and the second active region. In some embodiments, the first pass-gate transistor has a first gate structure extending lengthwise in the second direction, the first pull-down transistor includes a second gate structure extending lengthwise in the second direction, and the first gate structure, the second gate structure, and the dielectric feature are evenly spaced along the first direction. In some embodiments, a length of the dielectric feature measured in the second direction is larger than a height of the SRAM cell measured in the second direction.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
first and second cells; and
a transition region between the first and second cells,
wherein:
the first cell includes a first active region extending lengthwise in a first direction and into the transition region,
the first cell includes a plurality of first gate structures extending lengthwise in a second direction different from the first direction and spaced apart from each other in the first direction,
the second cell includes a second active region extending lengthwise in the first direction and into the transition region,
the second cell includes a plurality of second gate structures extending lengthwise in the second direction and spaced apart from each other in the first direction,
the transition region includes a first dielectric feature extending lengthwise in the second direction and a second dielectric feature extending lengthwise in the second direction,
the first dielectric feature divides the first active region into a first segment and a second segment, and
the second dielectric feature divides the second active region into a third segment and a fourth segment.

2. The semiconductor structure of claim 1, wherein the first gate structures and the second gate structures have a same gate pitch.

3. The semiconductor structure of claim 2, wherein the first dielectric feature is spaced apart from one of the first gate structures for the gate pitch, and the second dielectric feature is spaced apart from one of the second gate structures for the gate pitch.

4. The semiconductor structure of claim 1, wherein the second segment is fully within the transition region, and the fourth segment is fully within the transition region.

5. The semiconductor structure of claim 1, wherein the second segment of the first active region abuts the fourth segment of the second active region.

6. The semiconductor structure of claim 5, wherein the transition region includes a third gate structure disposed over an interface between the second segment of the first active region and the fourth segment of the second active region.

7. The semiconductor structure of claim 1, wherein the transition region includes a third dielectric feature extending lengthwise in the second direction and between the first and second dielectric features.

8. The semiconductor structure of claim 7, wherein the third dielectric feature separates the second segment of the first active region from the fourth segment of the second active region.

9. The semiconductor structure of claim 7, wherein the third dielectric feature has a length measured in the second direction that is smaller than the first and second dielectric features.

10. The semiconductor structure of claim 1, wherein the first cell includes a gate-cut feature abutting one of the first gate structures and extending lengthwise in the first direction, and wherein the gate-cut feature extends into the transition region.

11. A semiconductor structure, comprising:
a first cell with a first cell boundary, the first cell including:
a plurality of first active regions, and
a plurality of first gate structures across the first active regions;
a second cell with a second cell boundary, the second cell including:
a plurality of second active regions, and
a plurality of second gate structures across the second active regions; and
a transition region spanning from an edge of the first cell boundary to an edge of the second cell boundary, the transition region including:
a first dielectric feature separating the first active regions from the second active regions, the first and second active regions interfacing with opposing sidewalls of the first dielectric feature respectively.

12. The semiconductor structure of claim 11, wherein the first and second gate structures have a same gate pitch, and a width of the transition region is of an integer multiple of the gate pitch.

13. The semiconductor structure of claim 12, wherein the transition region has the width of one gate pitch.

14. The semiconductor structure of claim 12, wherein the transition region has the width of two gate pitches, and the transition region includes a second dielectric feature that is spaced apart from the first dielectric feature for one gate pitch.

15. The semiconductor structure of claim 12, wherein the transition region has the width of three gate pitches, and the first dielectric feature is located on a center line of the transition region.

16. The semiconductor structure of claim 12, wherein the transition region has the width of three gate pitches, and the transition region includes a second dielectric feature that is spaced apart from the first dielectric feature for two gate pitches and a third gate structure disposed between the first and second dielectric features.

17. A memory circuit, comprising:
a memory cell including a first pass-gate transistor and a first pull-down transistor formed on a first active region and a second pass-gate transistor and a second pull-down transistor formed on a second active region, wherein the first and second active regions extend lengthwise in a first direction; and
a dielectric feature extending lengthwise in a second direction different from the first direction, wherein the dielectric feature has a first sidewall interfacing with the first active region and the second active region.

18. The memory circuit of claim 17, comprising:
a logic cell including a third active region extending lengthwise in the first direction, wherein the dielectric feature has a second sidewall interfacing with the third active region.

19. The memory circuit of claim 17, wherein the first pass-gate transistor has a first gate structure extending lengthwise in the second direction, the first pull-down transistor includes a second gate structure extending lengthwise in the second direction, and the first gate structure, the second gate structure, and the dielectric feature are evenly spaced along the first direction.

20. The memory circuit of claim 17, wherein a length of the dielectric feature measured in the second direction is larger than a height of the memory cell measured in the second direction.
